(19) United States
(12) Patent Application Publication
(10) Pub. No.: US 2003/0159655 A1
(43) Pub. Date: Aug. 28, 2003

(54) Apparatus for depositing an insulation layer in a trench

(76) Inventors: Ping-Wei Lin, Hsinchu (TW); Gwo-Chyuan Kuoh, Keelung (TW); Chao Sheng Chiang, Kaohsiung (TW)

Correspondence Address: BIRCH STEWART KOLASCH & BIRCH, PO BOX 747, FALLS CHURCH, VA, 22040-0747, US

(21) Appl. No.: 10/222,931

(22) Filed: Aug. 19, 2002

(30) Foreign Application Priority Data
Feb. 26, 2002 (TW) 91103435

(51) Int. Cl. C23C 16/00

(52) U.S. Cl. 118/719; 118/715

(57) ABSTRACT

An apparatus for depositing an insulation layer in a trench. A wafer loader is used to load a wafer having a trench. A first HDP-CVD chamber adjoins the wafer loader, where the first HDP-CVD chamber is used to deposit a first insulation layer in the trench, and the first trench retains an opening. A vapor-etching chamber adjoins the first HDP-CVD chamber. The vapor-etching chamber is used to remove part of the first insulation layer to leave a remaining first insulation layer at the bottom of the trench and expose the sidewall of the trench above the remaining first insulation layer. A second HDP-CVD chamber adjoins the vapor-etching chamber, where the second HDP-CVD chamber fills the trench by depositing a second insulation layer. A wafer unloader adjoins the second HDP-CVD chamber.

### BACKGROUND OF THE INVENTION

1. Field of the Invention

The present invention relates to fabrication means for integrated circuits, and more particularly, to an apparatus for depositing an insulation layer in a trench.

2. Description of the Related Art

Semiconductor device geometry continues to decrease in size, providing more devices per fabricated wafer. Currently, some devices are fabricated with less than 0.25 μm spacing between features; in some cases there is as little as 0.18 μm spacing between features, which often takes the form of a trench.

An isolation technique called shallow trench isolation (STI) has been introduced to the fabrication of devices to reduce size. Isolation trenches are formed in a substrate between features, such as transistors. FIG. 1 is a schematic view of a traditional STI process.

In FIG. 1, a substrate 10 such as a silicon wafer is provided. A shield layer 12 composed of a pad oxide layer (not shown) and a SiN layer (not shown) is formed on part of the substrate 10. The shield layer 11 serves as a stacked mask defining an isolation area in the substrate 10.

In FIG. 1, using the shield layer 11 as a mask, part of the substrate 10 is etched to form a trench 15. A trench-filling material such as a SiO₂ layer 19 is deposited in the trench 15 once with a conventional high-density plasma chemical vapor deposition (HDP-CVD) apparatus.

FIG. 1 shows that a void may form when a trench with a narrow gap is filled by traditional process. For example, when the width of the trench 15 is less than 0.15 μm and/or the aspect ratio of the trench is greater than 4, a void 20 is easily formed in a SiO₂ layer 19 with the traditional process. Such a void seriously affects device reliability and yield, and hinders reduction in semiconductor device geometry.

### SUMMARY OF THE INVENTION

The object of the present invention is to provide an apparatus for depositing an insulation layer in a trench.

Another object of the present invention is to provide an apparatus for lowering the aspect ratio of a trench during a deposition process to fill the trench in a void-free manner.

In order to achieve these objects, an apparatus for depositing an insulation layer in a trench is provided. A wafer loader is used to load a wafer, wherein the wafer has a trench in a substrate. A first HDP-CVD chamber adjoins the wafer loader, wherein the first HDP-CVD chamber is used to deposit a first insulation layer in the trench, and the first trench retains an opening. A vapor-etching chamber adjoins the first HDP-CVD chamber. The vapor-etching chamber is used to remove part of the first insulation layer to leave a remaining first insulation layer at the bottom of the trench and to expose the sidewall of the trench above the remaining first insulation layer. A second HDP-CVD chamber adjoins the vapor-etching chamber, wherein the second HDP-CVD chamber fills the trench with a second insulation layer. A wafer unloader adjoins the second HDP-CVD chamber.

The present invention improves on the prior art in that the present apparatus has two HDP-CVD chambers and a vapor-etching chamber, which performs at least two depositions to fill the trench with insulation material. Thus, the invention can reduce the aspect ratio of the trench, thereby preventing voids forming during trench filling and ameliorating the disadvantages of the prior art. In addition, trench filling can be continuously performed in the apparatus, preventing particle issues.

### BRIEF DESCRIPTION OF THE DRAWINGS

The present invention can be more fully understood by reading the subsequent detailed description in conjunction with the examples and references made to the accompanying drawings, wherein:

FIG. 1 is a schematic view, according to the tradition STI process, that forms a void in a trench;

FIG. 2 is a simplified diagram of an embodiment of a trench-filling apparatus according to the present invention;

FIGS. 3˜5 are simplified diagrams of additional elements according to the present invention; and

FIGS. 6˜9 are sectional views, according to a deposition process, performed with the apparatus of the present invention.

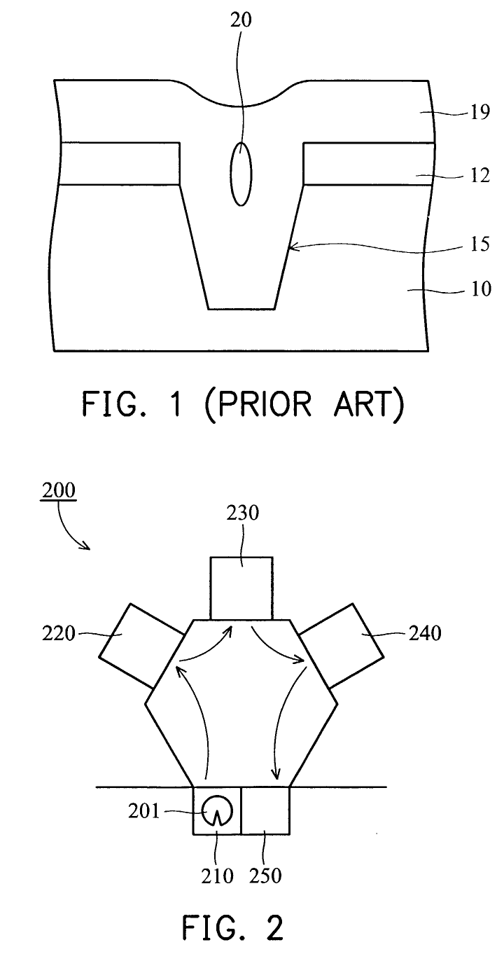

### DETAILED DESCRIPTION OF THE INVENTION

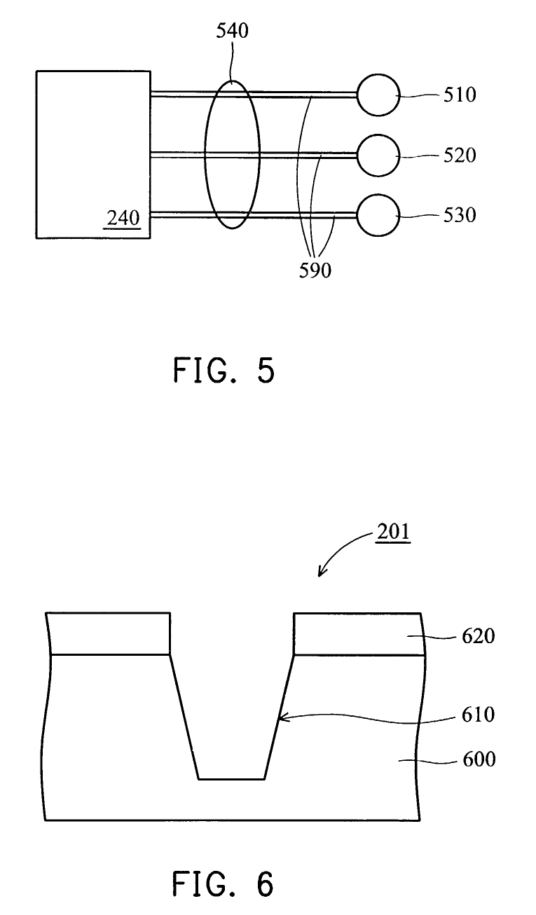

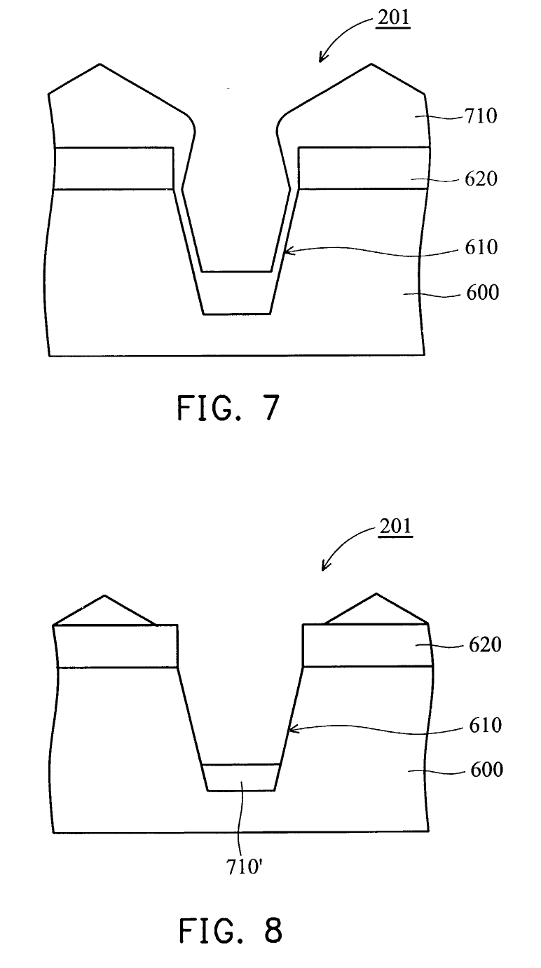

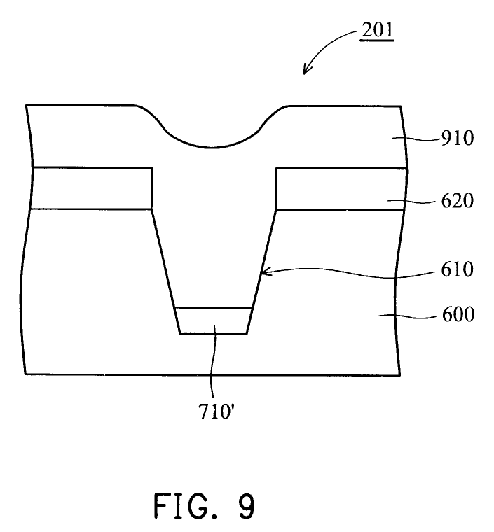

FIG. 2 is a simplified diagram of an embodiment of a trench-filling apparatus according to the present invention. FIGS. 6˜9 are sectional views, according to a deposition process, performed with the apparatus of the present invention.

In FIG. 2, an apparatus 200 for depositing an insulation layer in a trench is provided. The apparatus 200 includes a wafer loader 210, a first high-density plasma chemical vapor deposition (HDP-CVD) chamber 220, a vapor-etching chamber 230, a second HDP-CVD chamber 240 and a wafer unloader 250. The apparatus 200 is suitable for application to a wafer 201 that has a trench 610 in a substrate 600, as shown as FIG. 6. The symbol 620 is a shield layer formed on part of the substrate 600.

In FIG. 2, the wafer loader 210 is used to load the wafer 201. The sectional view of the wafer 201 at this stage is shown in FIG. 6.

In FIG. 2 and FIG. 7, a first high-density plasma chemical vapor deposition (HDP-CVD) chamber 220 is disposed to adjoin the wafer loader 210. The first HDP-CVD chamber 220 is used to deposit a first insulation layer 710 in the trench 610. The first trench 610 is not filled up with the first insulation layer 710, retaining an opening. The first insulation layer 710 may be a SiO₂ layer.

In FIG. 2 and FIG. 8, a vapor-etching chamber 230 is disposed to adjoin the first HDP-CVD chamber 220. The vapor-etching chamber 230 is used to partially etch back the first insulation layer 710 to leave a remaining first insulation layer 710′ at the bottom of the trench 610 and to expose the sidewall of the trench 610 above the remaining first insulation layer 710′.

In FIG. 2 and FIG. 9, a second HDP-CVD chamber 240 is disposed to adjoin the vapor-etching chamber 230. The second HDP-CVD chamber 240 fills the trench 610 with a second insulation layer 910. The second insulation layer 910 may be a SiO₂ layer.

In FIG. 2, a wafer unloader 250 is disposed to adjoin the second HDP-CVD chamber 240. The sectional view of the wafer 201 at this stage is shown in FIG. 9. In addition, the apparatus 200 has a transport system (not shown). The transport system, such as a robot, is used to deliver the wafer 201 to the wafer loader 210, the first HDP-CVD chamber 220, the gas etching chamber 230, the second HDP-CVD chamber 240 or the wafer unloader 250.

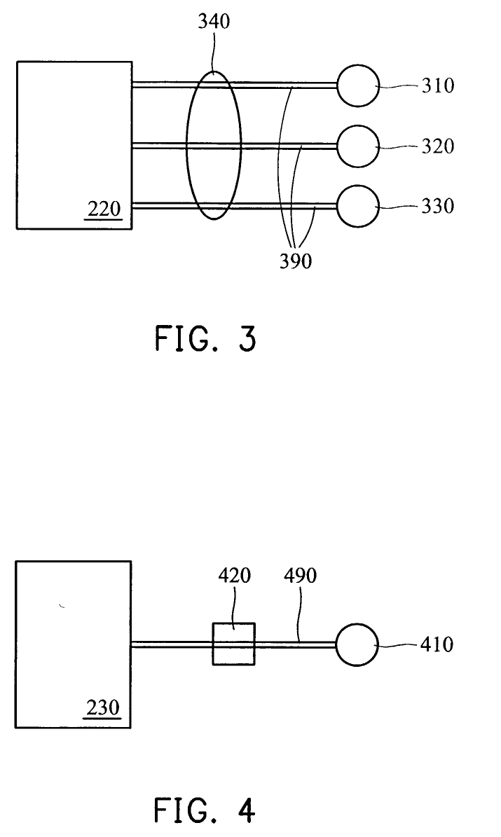

In FIG. 3, the apparatus 200 can further comprise a first silane (SiH₄) gas supply system 310, a first inert gas supply system 320, a first oxygen gas supply system 330, a first gas control system 340 and a first piping system 390. The first silane (SiH₄) gas supply system 310 connects the first HDP-CVD chamber 220 by means of the first piping system 390. The first inert gas supply system 320, such as argon (Ar) or helium (He), connects the first HDP-CVD chamber 220 by means of the first piping system 390. The first oxygen gas supply system 330 connects the first HDP-CVD chamber 220 by means of the first piping system 390. The first gas control system 340 controls the flow rate and time of the silane gas, the inert gas, and the oxygen gas. The first gas control system 340 is disposed in the manner of the first piping system 390. That is, the first gas control system 340 is located between the first HDP-CVD chamber 220 and the first gas supply systems 310, 320, 330.

In FIG. 4, the apparatus 200 further comprises a hydrofluoric acid (HF) vapor supply system 410, a HF vapor control system 420 and a second piping system 490. The HF vapor supply system 410 connects the vapor-etching chamber 230 by means of the second piping system 490. The HF vapor control system 420 controls the flow rate and time of the HF vapor. The HF vapor control system 420 is disposed in the manner of the second piping system 490. That is, the HF vapor control system 420 is located between the vapor-etching chamber 230 and the HF vapor supply system 410.

In FIG. 5, the apparatus 200 further comprises a second silane (SiH₄) gas supply system 510, a second inert gas supply system 520, a second oxygen gas supply system 530, a second gas control system 540 and a third piping system 590. The second silane (SiH₄) gas supply system 510 connects the second HDP-CVD chamber 240 by means of the third piping system 590. The second inert gas supply system 520, such as argon (Ar) or helium (He), connects the second HDP-CVD chamber 240 by means of the third piping system 590. The second oxygen gas supply system 530 connects the second HDP-CVD chamber 240 by means of the third piping system 590. The second gas control system 540 controls the flow rate and time of the silane gas, the inert gas, and the oxygen gas. The second gas control system 540 is disposed in the manner of the third piping system 590. That is, the second gas control system 540 is located between the second HDP-CVD chamber 240 and the second gas supply systems 510, 520, 530.

The present invention provides an apparatus for depositing an insulation layer in a trench, especially in a trench having a narrow and/or high-aspect-ratio gap. The apparatus can perform at least two depositions to fill the trench with insulation material. Thus, the apparatus of the present invention can reduce the aspect ratio of the trench; thereby preventing voids forming during trench filling. Additionally, trench filling can be continuously performed in the apparatus, preventing particle issues.

Finally, while the invention has been described by way of example and in terms of the above, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An apparatus for depositing an insulation layer in a trench, comprising:
a wafer loader for loading a wafer, wherein the wafer has a trench in a substrate;
a first high-density plasma chemical vapor deposition (HDP-CVD) chamber adjoining the wafer loader, wherein the first HDP-CVD chamber is used to deposit a first insulation layer in the trench, and the first trench retains an opening;
a vapor-etching chamber adjoining the first HDP-CVD chamber, wherein the vapor-etching chamber is used to partially etch back the first insulation layer to leave a remaining first insulation layer at the bottom of the trench and to expose the sidewall of the trench above the remaining first insulation layer;
a second HDP-CVD chamber adjoining the vapor-etching chamber, wherein the second HDP-CVD chamber fills the trench with a second insulation layer; and
a wafer unloader adjoining the second HDP-CVD chamber.

2. The apparatus according to claim 1, further comprising:
a first silane (SiH₄) gas supply system connecting the first HDP-CVD chamber;
a first inert gas supply system connecting the first HDP-CVD chamber;
a first oxygen gas supply system connecting the first HDP-CVD chamber; and
a first gas control system for controlling the flow rate and time of the silane gas, inert gas and oxygen gas, wherein the first gas control system is located between the first HDP-CVD chamber and the first gas supply systems.

3. The apparatus according to claim 1, further comprising:
a hydrofluoric acid (HF) vapor supply system connecting the vapor-etching chamber; and
a HF vapor control system for controlling the flow rate and time of the HF vapor, wherein the HF vapor control system is located between the vapor-etching chamber and the HF vapor supply system.

4. The apparatus according to claim 1, further comprising:
a second silane (SiH₄) gas supply system connecting the first HDP-CVD chamber;
a second inert gas supply system connecting the first HDP-CVD chamber;
a second oxygen gas supply system connecting the first HDP-CVD chamber; and
a second gas control system for controlling the flow rate and time of the silane gas, inert gas and oxygen gas, wherein the second gas control system is located between the second HDP-CVD chamber and the second gas supply systems.

5. The apparatus according to claim 2, wherein the inert gas is argon (Ar) or helium (He).

6. The apparatus according to claim 4, wherein the inert gas is argon (Ar) or helium (He).

7. The apparatus according to claim 1, wherein the first insulation layer is a SiO₂ layer.

8. The apparatus according to claim 1, wherein the second insulation layer is a SiO₂ layer.

9. The apparatus according to claim 1, further comprising:
a transport system delivering the wafer to the wafer loader, the first HDP-CVD chamber, the gas etching chamber, the second HDP-CVD chamber or the wafer unloader.
